(19) United States
(12) Patent Application Publication
(10) Pub. No.: US 2002/0125570 A1
(43) Pub. Date: Sep. 12, 2002

(54) Ball grid array semiconductor package structure to avoid high frequency interference

(76) Inventors: Yu-Chun Wu, Kaohsiung Hsien (CN); Chi-Tsung Chiu, Kaohsiung (CN); Li-Chuan Chang Chien, Kaohsiung (CN); Yung-I Yeh, Kaohsiung (CN)

Correspondence Address: NIXON PEABODY, LLP, 8180 GREENSBORO DRIVE, SUITE 800, MCLEAN, VA, 22102, US

(21) Appl. No.: 09/800,822

(22) Filed: Mar. 8, 2001

(51) Int. Cl. H01L 23/48; H01L 23/52; H01L 29/40; H01L 23/528

(52) U.S. Cl. 257/738; 257/780; 257/781

(57) ABSTRACT

A BGA semiconductor package structure that is able to avoid high frequency interference has at least one non-ball mounting area on a bottom face of a substrate, wherein high frequency bump balls are mounted abreast on the non-ball mounting ball area. When the BGA package device is mounted on a PCB, the non-ball mounting area correspond the electric wires, such that the electric wires which are formed on the PCB are able to transmit high frequency signals and connect the high frequency bump balls. Thus, when the high frequency signals are transmitted via the electric wires, the high frequency signals do not affect other signals transmitted via other electric wires.

### BACKGROUND OF THE INVENTION

1. Field of the Invention

The present invention relates to a ball grid array (BGA) semiconductor package structure that is able to avoid high frequency interference, and more particularly to a BGA semiconductor package structure that has at least one non-ball mounting area on a bottom face of a substrate.

2. Description of Related Art

A conventional ball grid array semiconductor package structure is shown in FIG. 5. Generally the conventional BGA package structure has a bottom face (51) of a substrate (50), and a ball mounting area that has bump balls (512) mounted in a matrix on the bottom face (51).

With reference to FIG. 6, the substrate (50) of the conventional BGA package device is mounted on a printed circuit board (PCB) (60), and all the bump balls (512) correspond to electric wires (61) formed on the PCB (60). One of the bump balls (512), a high frequency signal bump ball (511), for transmitting high frequency signal is surrounded by the bump balls (512) which are transmitting signals other than high frequency signals. In order to connect via a electric wire (61) the high frequency signal bump ball (511) to a pin of a component on the PCB, the electric wire (61) have to be routed between two adjacent bump balls (512) connected to pins of other components via electric wires (62). Therefore the electric wire (61) affects the signals in the adjacent electric wires (62) when the bump balls (512) are transmitting signals-via the electric wires (62). Furthermore, the length of the electric wire (61) is long due to the necessary routing, and hence the resistance and capacitance of the electric wire (61) are high. Therefore a malfunction occurs if a high frequency integrated circuit is mounted on the PCB packages by the aforementioned BGA package.

To overcome the shortcomings, the present invention tends to provide an improved BGA package structure for a high frequency integrated circuit to mitigate and obviate the aforementioned problems.

### SUMMARY OF THE INVENTION

The objective of the present invention is to provide a ball grid array (BGA) semiconductor package structure that is able to avoid high frequency interference. The structure has at least one non-ball mounting area on a bottom face of a substrate. The non-ball mounting area corresponds to electric wires on a printed circuit board (PCB), such that the electric wires are able to transmit high frequency signals when the BGA package is mounted on the PCB.

Other objects, advantages, and novel features of the invention will become more apparent from the following detailed description when taken in conjunction with the accompanying drawings.

### BRIEF DESCRIPTION OF THE DRAWINGS

FIG. 1 is a top plan view of a first preferred embodiment of a BGA semiconductor package structure that is avoidable high frequency interference, wherein the structure is mounted on a printed circuit board in accordance with the present invention;

FIG. 2 is a cross section view taken from line 2-2 shown in FIG. 1;

FIG. 3 is a top plan view of a second preferred embodiment of a BGA semiconductor package structure that is avoidable high frequency interference, wherein the structure is mounted on a printed circuit board in accordance with the present invention;

FIG. 4 is a cross section view taken from line 4-4 shown in FIG. 3;

FIG. 5 is bottom plan view of a conventional BGA package; and

FIG. 6 is top plan view of a conventional BGA package structure as shown in FIG. 5 and the BGA package is mounted on a printed circuit board.

### DETAILED DESCRIPTION OF THE PREFERRED EMBODIMENT

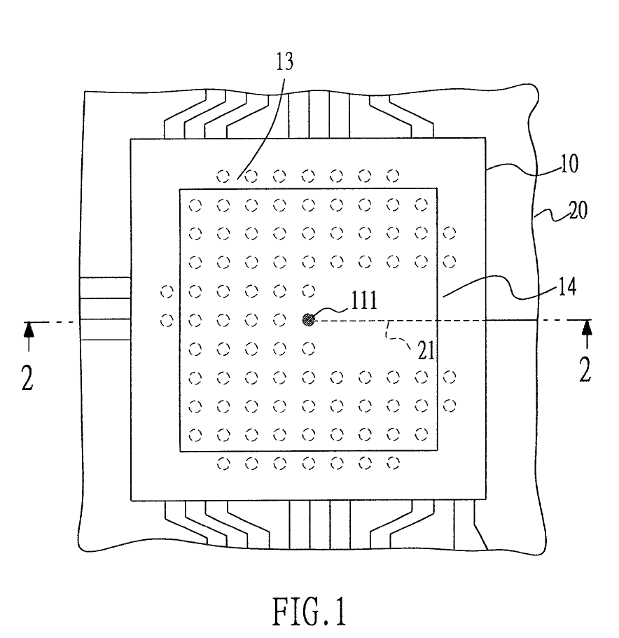

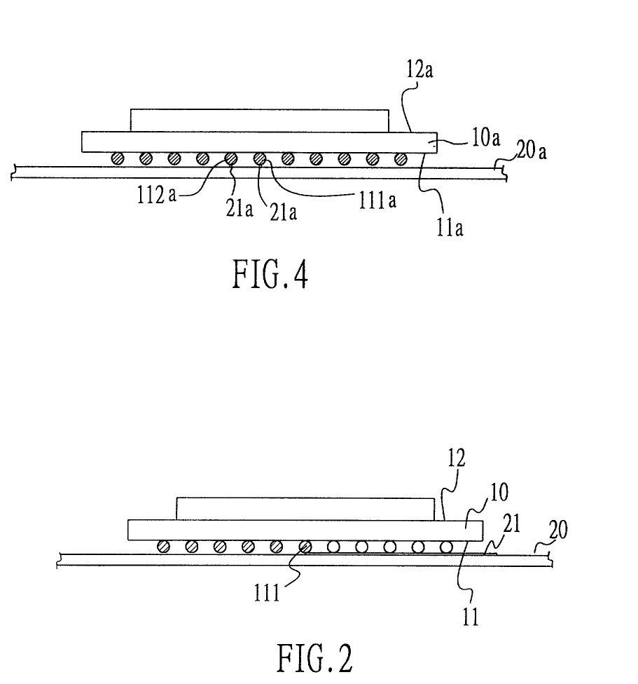

FIG. 1 shows a structure of a ball grid array (BGA) semiconductor package structure which includes a substrate having a bottom face (11) and an upper face (12), as shown in FIG. 2, a ball mounting area (13) on the bottom face (11), at least one non-ball mounting area (14) on the bottom face (11), and at least one high frequency signal bump ball (111) mounted on jointing peripheries of the ball mounting area (13) and the non-ball mounting area (14).

With reference to FIG. 1, bump balls (113) are mounted on the ball mounting area (13) in an irregular manner however equally spaced apart from each other. A width of the non-mounting bump area (14) extends from the high frequency signal bump ball (111) in up and down directions by at least two ball pitches. A length of the non-ball mounting area (14) extends between the high frequency signal bump ball (111) and an edge of the bottom face (11), shown in FIG. 2.

With reference to FIG. 2, the substrate (10) of the BGA package device is mounted on a PCB (20), and the high frequency signal bump ball (111) is mounted on a corresponding electric wire (21) that is formed on the PCB (20), wherein the electric wire (21) is corresponded below the non-ball mounting area (14) shown in FIG. 1.

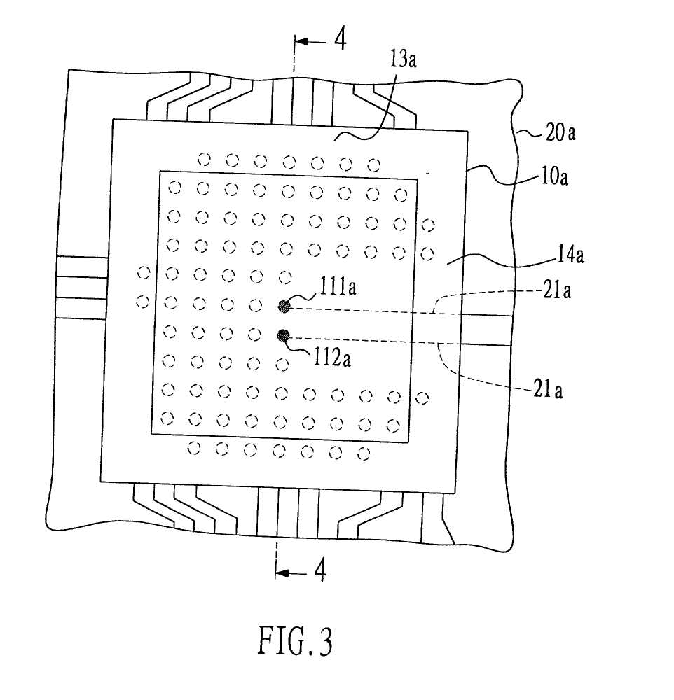

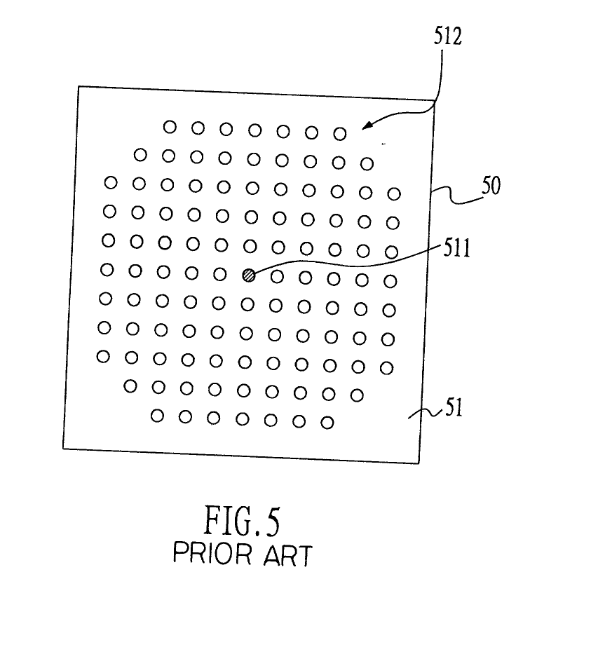

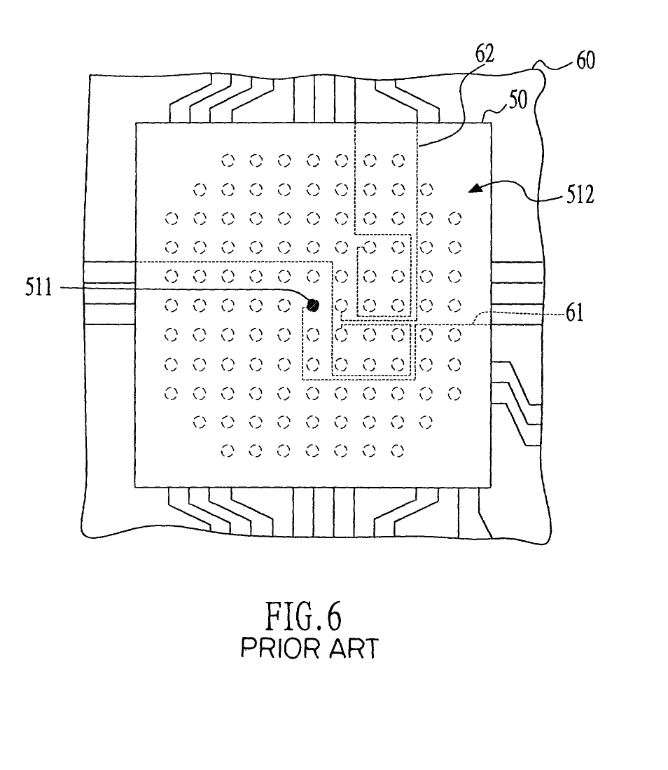

With reference to FIG. 3, a second preferred embodiment of the invention is shown. Two high frequency signal bump balls (111a,112a) are mounted abreast on the ball mounting area (13a), wherein the two high frequency signal bump balls (111a,112a) are mounted adjacent to the periphery of the non-ball mounting area (14a). A width of the non-ball mounting area (14a) extends from each one of the two high frequency signal bump balls (111a,112a) and respectively upwardly and downwardly by at least two ball pitches. A length of the non-ball mounting area (14a) extends between the two high frequency signal bump balls (111a,112a) and an edge of the bottom face (11a), shown in FIG. 4.

With reference to FIG. 3 and FIG. 4, the substrate (10a) of the BGA package component is mounted on the PCB (20a), and the two high frequency signal bump balls (111a,112a) are mounted on two corresponding abreast electric wires (21a) that are formed on the PCB (20a). Both abreast electric wires (21a) are formed below the non-ball mounting area (14a) when the substrate (10a) is mounted on the PCB (20a). Because both abreast electric wires (21a) transmit the same high frequency signal, Electromagnet Interference (EMI) is avoided by the abreast electric wires (21a).

As mentioned above, the width and length of the non-ball mounting area are decided by the positions of the high frequency signal bump balls. Hence when the substrate of the BGA package is mounted on the PCB, the electric wires that are connected to the high frequency signal bump balls are below the non-ball mounting area. Thus, when the high frequency signal is transmitted via the electric wire, the high frequency signals do not affect other signals transmitted via other electric wires. The electric wires for transmitting high frequency signals are not routed between adjacent bump balls, therefore the length of the electric wires is short. The EMI produced from the high frequency signal transmission via the signal electric wire is avoided when two abreast electric wires transmit the same high frequency signal.

Although the present invention has been explained in relation to its preferred embodiment, it is to be understood that many other possible modifications and variations can be made without departing from the spirit and scope of the invention as hereinafter claimed.

What is claimed is

1. A BGA semiconductor package structure adapted to attach to a PCB to avoid high frequency interference, the structure comprising:
a substrate;
a ball mounting area formed on a bottom face of the substrate;
multiple bump balls irregularly mounted on the ball mounting area, and arranged with equal space with each other; at least one non-ball mounting area adjacent the ball mounting area; and
at least one high frequency signal bump ball mounted on jointing peripheries of the ball mounting area and the non-ball mounting area.

2. The BGA semiconductor package structure to avoid high frequency interference, the structure as claimed in claim 1, wherein a width of the non-ball mounting area are four ball pitches, and a length of the non-ball mounting area extends between the high frequency signal bump ball and an edge of the bottom face.

3. The BGA semiconductor package structure to avoid high frequency interference, the structure as claimed in claim 1, wherein a width of the non-ball mounting area extends from the at least one high frequency signal bump ball by at least two ball pitches, and a length of the non-ball mounting area extends between the high frequency signal bump ball and an edge of the bottom face.

4. A BGA semiconductor package structure adapted to attach to a PCB to avoid high frequency interference, the structure comprising:
a substrate;
a ball mounting area defined on a bottom face of the substrate;
at least one non-ball mounting area adjacent the ball mounting area; and
at least two high frequency signal bump balls mounted on the ball mounting area, wherein the two high frequency signal bump balls transmit a same high frequency signal and are mounted abreast adjacent to a periphery of the non-ball mounting area.

5. The BGA semiconductor package structure to avoid high frequency interference, the structure as claimed in claim 4, wherein a width of the non-ball mounting area is five ball pitches, and a length of the non-ball mounting area extends between the two high frequency signal bump balls and an edge of the bottom face.

6. The BGA semiconductor package structure to avoid high frequency interference, the structure as claimed in claim 4, wherein a width of the non-ball mounting area extends from a respect one of the high frequency bump balls by at least two ball pitches with a ball pitch defined between the at least two bump balls, and a length of the non-ball mounting area extends between the two high frequency signal bump balls and an edge of the bottom face.
